(19) United States
(12) Patent Application Publication
(10) Pub. No.: US 2010/0188136 A1
(43) Pub. Date: Jul. 29, 2010

(54) DYNAMIC THERMAL MANAGEMENT SYSTEM AND METHOD

(75) Inventors: David Dean Baker, Gilbert, AZ (US); Mark Albers, Mesa, AZ (US)

Correspondence Address: STEPTOE & JOHNSON LLP, 2121 AVENUE OF THE STARS, SUITE 2800, LOS ANGELES, CA, 90067, US

(73) Assignee: ROCKFORD CORPORATION, Tempe, AZ (US)

(21) Appl. No.: 12/360,358

(22) Filed: Jan. 27, 2009

(51) Int. Cl. H03K 3/011

(52) U.S. Cl. 327/512

(57) ABSTRACT

A dynamic thermal management system regulates heat dissipation of a system or device including a power supply and an amplifier. The heat dissipation from the power supply and amplifier are regulated to distribute heat more evenly across a heat sink shared by the amplifier and the power supply.

### FIELD

Embodiments disclosed herein relate generally to a dynamic thermal management system, and more particularly, to a system and method for managing thermal output of an amplifier and power supply.

### BACKGROUND

In audio systems, a power supply drives an amplifier which in turn drives an audio output, such as a speaker. Since the power supply and amplifier generate heat at different rates, the amplifier may overheat before the power supply, and the amplifier may need to be shut down to prevent damage to the amplifier. However, since the power supply has not generated as much heat as the amplifier, it has “excess” heat capacity when the amplifier reaches its thermal limit.

Many fully regulated power supply systems maintain a fixed secondary voltage across a wide primary voltage window. One benefit of such a system is that the heat dissipation of the amplifier can be reduced by reducing the voltage at the amplifier. However, fully regulated power supply systems require expensive components and complex designs.

Other systems improve heat generating efficiency of an amplifier without balancing heat dissipation between the amplifier and a power supply. One such system is shown in U.S. Pat. No. 6,975,172 to Craynon. Craynon detects an output signal from an amplifier and determines whether it is within a predetermined range. If so, the power rails to the amplifier are adjusted to predetermined levels that increase the heat generation efficiency of the amplifier. Craynon asserts that this system increases heat generation efficiency of the amplifier. However, the Craynon system fails to address an imbalance of heat dissipation from an amplifier and a power supply.

A system and method are needed that balance a heat dissipation of an amplifier and power supply, so that a system containing the amplifier and power supply balances heat dissipation on a heat sink at a low cost.

### SUMMARY

Briefly, and in general terms, there is disclosed a dynamic thermal management system. More particularly, there is disclosed a system and method that manages the thermal output of an amplifier and power supply.

A thermal management system may include a power supply, an amplifier connected to the power supply, an output device connected to the amplifier, and a monitoring circuit for managing a heat output of the power supply and the amplifier. The monitoring circuit may determine an output heat level of each of the power supply and amplifier and balance a heat output of the amplifier with respect to the power supply. The audio device may be a speaker, and the amplifier may be a fixed rail amplifier. The power supply may include a battery.

The thermal management system may include a pulse width modulation circuit connected between the monitoring circuit and the power supply. The monitoring circuit may monitor an input signal to the amplifier, and may cause the pulse width modulation circuit to reduce a duty cycle of a modulated signal to the power supply when the input signal is below a predetermined level.

The monitoring circuit may cause the pulse width modulation circuit to reduce the duty cycle of the modulated signal to a level between approximately 40% and 50% of a full duty cycle.

The thermal management system may include a pulse width modulation circuit connected between the monitoring circuit and the power supply, and the monitoring circuit may cause the pulse width modulation circuit to reduce a duty cycle of a modulated signal to the power supply when a heat level of at least one of the power supply and the amplifier reaches a predetermined level.

The monitoring circuit may cause the pulse width modulation circuit to reduce the duty cycle of the modulated signal to 50% when the heat level of at least one of the power supply and the amplifier reaches a predetermined level.

The thermal management system may include a heat sink for sinking heat from the power supply and the amplifier, and the monitoring circuit may monitor the heat level of the heat sink to determine whether to reduce the duty cycle of the modulated signal to the power supply.

The thermal management system may include a sensor, and the monitoring circuit may monitor the heat level of the heat sink via the sensor.

A device for supplying signals to an audio device may include a power supply, an amplifier connected to the power supply and to the audio device, and a monitoring circuit for managing a heat output of the power supply and the amplifier.

The method for managing a heat output of a power management device for supplying signals to an output device may include monitoring an input signal to an amplifier, determining whether an input signal level is below a predetermined level, and reducing a duty cycle of modulated signal from a pulse width modulator to the power supply when the input signal level is below a predetermined level.

The predetermined level of the input signal may correspond to one third of full output power.

The heat level of at least one of the power supply and the amplifier may be monitored, and the duty cycle of the modulated signal may be reduced when the heat level exceeds a predetermined level.

The power management device may include a monitoring circuit and a heat sink, the heat sink may sink heat from the power supply and the amplifier, and the monitoring circuit may monitor the heat level of the power supply and the amplifier by monitoring a heat level of the heat sink.

Other features and advantages will become apparent from the following detailed description, taken in conjunction with the accompanying drawings, which illustrate by way of example, the features of the various embodiments.

### BRIEF DESCRIPTION OF THE DRAWING

The invention is illustrated by way of example and not limitation in the figures of the accompanying drawings. In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

FIG. 1 illustrates a block diagram of a heat management system;

FIG. 2 illustrates the relationship between power, temperature, and the duty cycle;

FIG. 3 is a graph comparing a system that includes a first stage of a thermal management system with one that does not have a thermal management system;

FIG. 4 illustrates an effect of a second stage of a thermal management system;

FIG. 5 illustrates a simple schematic of a portion of a thermal management system; and

FIG. 6 represents a top view of a power supply and amplifier sharing a single heat sink.

### DETAILED DESCRIPTION

The various embodiments described below are provided by way of illustration only and should not be construed to limit the claimed invention. Those skilled in the art will readily recognize various modifications and changes that may be made to the disclosed embodiments without departing from the scope of the claimed invention. By way of non-limiting example, it will be appreciated by those skilled in the art that particular features or characteristics described in reference to one figure or embodiment may be combined as suitable with features or characteristics described in another figure or embodiment. Further, those skilled in the art will recognize that the devices, systems, and methods disclosed herein are not limited to one field.

A dynamic thermal management system may be used to manage thermal dissipation of any two electronic components. One of the components may be a power supply, the other component may be an amplifier, and the power supply drives the amplifier. The amplifier may drive an audio device, such as an audio speaker. The power supply and amplifier may share a single heat sink. Other electrical components may also share the heat sink.

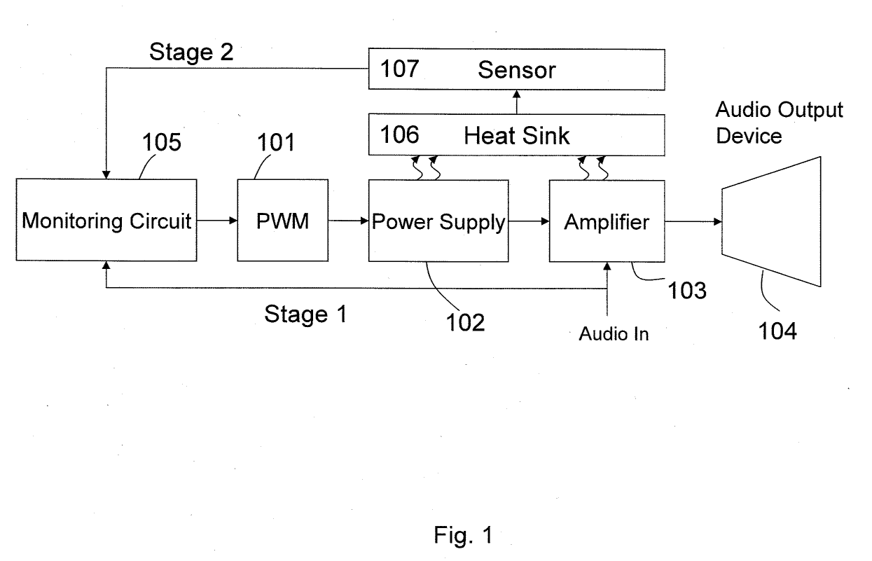

FIG. 1 shows a block diagram of a dynamic thermal management system. A pulse-width modulator 101 drives a power supply 102. The power supply may be, for example, a DC-DC converter connected to a battery. However, any other power supply may be used. The power supply 102 drives the amplifier 103. The amplifier may be a fixed rail amplifier, although any suitable amplifier may be used. The power supply 102 outputs voltage rails to the amplifier 103. A voltage level of the voltage rails may be determined by a duty cycle of the signal from the pulse width modulator 101 to the power supply 102.

The amplifier 103 receives an audio input signal and drives an audio output device 104. The audio input signal is amplified by the amplifier 103 based on the voltage levels of the voltage rails from the power supply 102 to the amplifier 103. The audio output device 104 may be an audio speaker. Although in this embodiment the amplifier 103 drives an audio output device 104, a system utilizing a dynamic thermal management system or method is not limited to an audio output device.

A heat sink 106 dissipates heat from the power supply 102 and the amplifier 103. Its temperature may be monitored by a sensor 107 connected to a monitoring circuit 105. One heat sink may be used to dissipate heat from both the power supply and the amplifier. By using only one heat sink to dissipate heat from both the power supply and the amplifier, heat dissipation from the two electronic components may be averaged across the heat sink to improve performance.

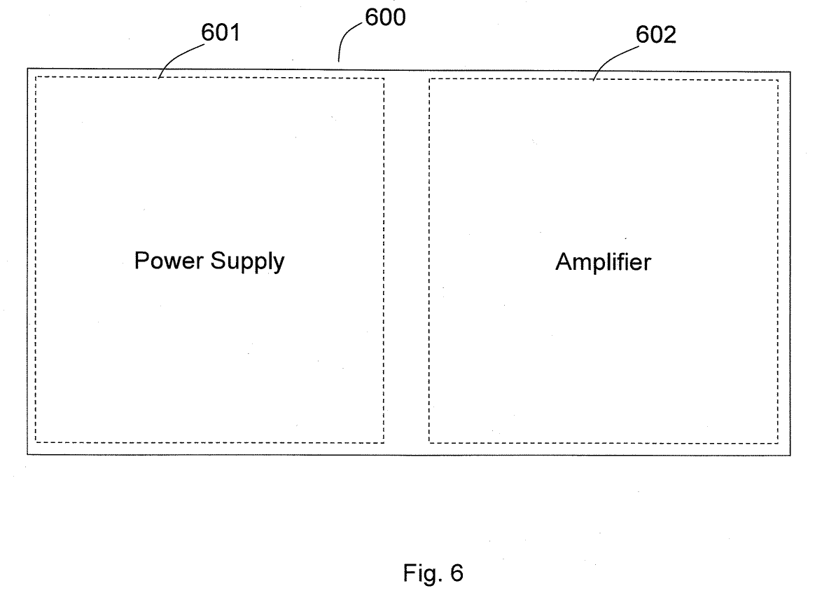

FIG. 6 discloses such a configuration. Heat sink 600 is connected to a power supply stage 601 of a system. The heat sink 600 is also connected to an amplifier stage 602 of the system. The power supply 601 and amplifier 602 each generate heat at different rates. Generally, when the power supply 601 and amplifier 602 operate below full power, the amplifier 602 generates heat at a faster rate than the power supply 601. As a result, the portion of the heat sink 600 connected to the amplifier 602 dissipates more heat than the portion connected to the power supply 601. If the heat dissipation on the heat sink 600 can be balanced, the amplifier 602 may operate for a longer period of time without reaching its thermal limit, or the maximum temperature at which it is safe to operate the amplifier.

In a first stage, or stage 1, of the dynamic thermal management system, the monitoring circuit 105 monitors the audio input signal to the amplifier 103. If the input signal falls below a predetermined level, the monitoring unit 105 signals the PWM 101 to reduce the duty cycle of its output signal to the power supply 102. The input signal of the amplifier 103 may directly correspond to an output power level of the amplifier. The reduction of the duty cycle causes the power supply 102 to operate less heat-efficiently, generating more heat per watt of output power. This causes the power supply to dissipate more heat via the heat sink 106. However, by operating at a lower power level, the amplifier 103 operates generates less heat per watt of output power. This causes the amplifier to dissipate less heat via the heat sink 106. Decreasing the duty cycle causes the area of the heat sink 106 corresponding with the amplifier 103 to decrease in temperature, or increase at a slower rate, since the amplifier generally operates at a more heat-efficient state when driven at low power that at higher power levels. The area of the heat sink 106 corresponding with the power supply 102 increases in temperature, since the power supply is less heat-efficient at a lower power.

The output from the power supply 102 to the amplifier via the voltage rails provides a power output range within which the amplifier 103 can operate. Decreasing the duty cycle of the signal from the pulse width modulator 101 to the power supply 102 tends to decrease the voltages on the voltage rails to the amplifier 103 while still providing the amplifier with sufficient power to output an amplified signal that corresponds to the input signal to the amplifier.

For example, a power supply may output a maximum rail voltage of 45V for a 350 W output amplifier. In a system in which stage 1 is implemented, when the amplifier output is 10 W, the pulse width modulator would reduce the duty cycle to the power supply. As a result, the power supply may output only 17V to the amplifier along the voltage rails. Since 17V voltage rails would allow the amplifier to output about 65 W maximum, reducing the duty cycle would not adversely affect the output power capability of the amplifier when the amplifier outputs 10 W. Likewise, reducing the duty cycle to 40-50% does not adversely affect the output power capability of the amplifier when the amplifier operates about or below 30% of maximum output power.

The change in duty cycle of the pulse width modulator allocates heat across the heat sink more symmetrically than it would otherwise be, reducing the rate at which the heat sink approaches capacity. When the thermal management system is used with an audio device, the change in duty cycle of the pulse width modulator is not noticeable by a listener.

This first stage of the dynamic thermal management system may be triggered when the audio input level corresponds to an amplifier output power level of between 0% and 30% of its maximum power output. The duty cycle of the pulse width modulator may be maintained between and including 40% and 50% during the first stage. If the input signal increases and causes the output power to increase above 30% of the output maximum, the duty cycle may be increased over time until it reaches 100%. Alternatively, the duty cycle may increase linearly as a function of audio input power. Although the first stage may be triggered at an input power level corresponding to an output power of 30% and below of the maximum power output, any appropriate percentage may be used to trigger the first stage, depending on the characteristics of the circuit.

For example, if a system has a maximum output power of 100 W, stage 1 would engage to decrease the duty cycle of the signal from the PWM to the power supply when the input signal results in an output power of 30 W or less. If the output power level is very low, such as around 1 W, the duty cycle may be maintained closer to 40%. If the output power level is close to 29 W, the duty cycle may be maintained near 50%. If the input power level rises, causing the output power to rise above 30 W, the duty cycle may increase to a full 100%.

In a second stage, or stage 2, of the dynamic thermal management system, the monitoring unit 105 monitors the temperature of the power supply 102 and amplifier 103 via a sensor 107. The sensor 107 may, for example, measure the temperature of the heat sink 106. If the heat sink temperature exceeds a predetermined level, the monitoring unit 105 may signal the PWM 101 to reduce the duty cycle of the pulse width modulator of the signal to the power supply 102. The predetermined temperature level depends on the thermal ratings of the power supply and amplifier. The level should be selected so that the second stage engages before the amplifier or power supply are forced to shut down to prevent damage to the components or other circuitry. According to one embodiment, the sensor is a thermistor which converts the heat sink temperature to a voltage. If the voltage reaches a predetermined level, it triggers stage 2.

According to one embodiment, stage 2 is triggered and disengaged at different temperatures. For example, the monitoring circuit 105 may trigger stage 2 when the heat sink 106 reaches 75 degrees C. If the heat sink cools, the monitoring unit 105 may disengage stage 2 when the heat sink reaches 70 degrees C.

The duty cycle of the pulse width modulator may be reduced to a fixed level of 50% in the second stage. Reducing the duty cycle reduces the thermal load on a portion of the heat sink 106 corresponding to the amplifier 103 and increases the thermal load on a portion of the heat sink corresponding to the power supply 102.

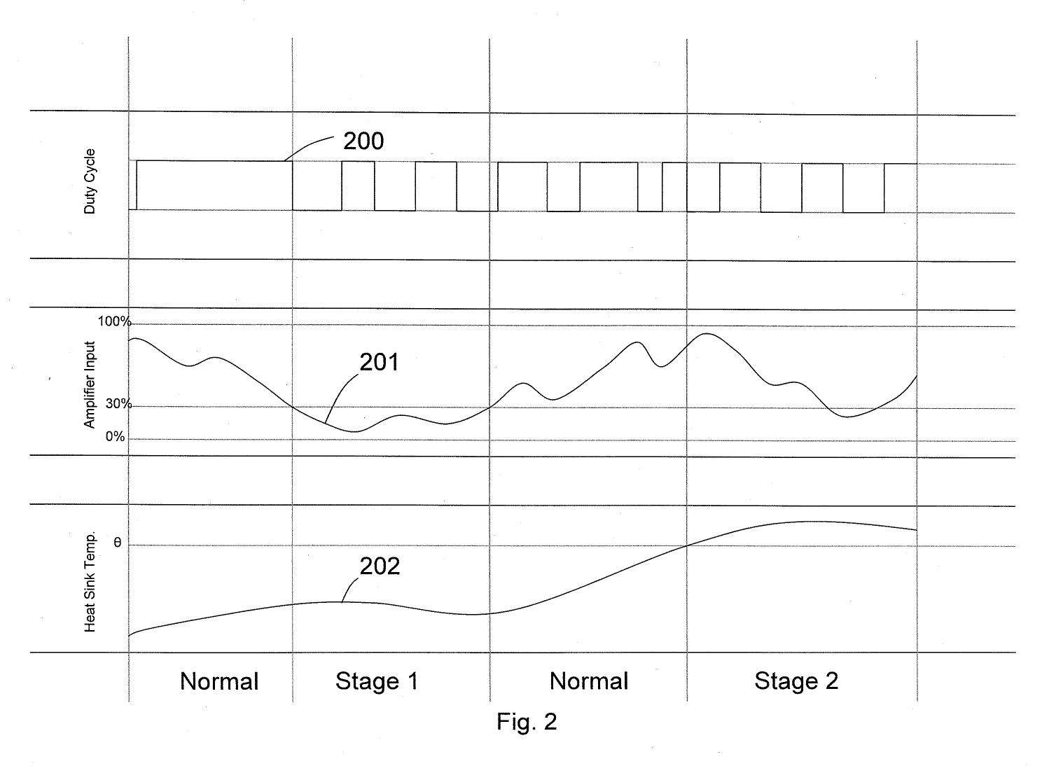

FIG. 2 illustrates how the duty cycle of the pulse width modulator of the signal driving the power supply changes based on the audio input signal and the temperature of a heat sink. The heat dissipation of a heat sink connected to a power supply and an amplifier may be balanced by adjusting a duty cycle from a PWM to the power supply in two stages. In the first stage a circuit monitors the input signal to the amplifier and adjusts the duty cycle according to the input power. In the second stage, the temperature of the heat sink is monitored, and the duty cycle is reduced when the temperature rises above a certain level.

Both stages balance dissipation of the heat sink by allowing the power supply to operate less heat-efficiently, and allowing the amplifier to operate more heat-efficiently. Although the combined heat efficiency of the amplifier and the power supply may not change, the capability of the heat sink to dissipate the heat increases, since the heat is balanced across the heat sink. The combined heat efficiency of the amplifier and power supply may remain substantially the same whether or not the thermal management system is used.

As shown in FIG. 2, in normal operation mode, the duty cycle of the pulse width modulator 200 operates at 100%. If the amplifier input 201 falls below a predetermined power level, the duty cycle is reduced to a predetermined value between 40% and 50%. The predetermined level may be 30% of total output power, or any other predetermined level. When used in an audio system, reducing the duty cycle to the power supply when the amplifier input is a low percentage of its possible power input results in a change in audio signal that is not noticeable by a listener.

The duty cycle of the pulse width modulator value may also track the amplifier input power percentage. For example, if the predetermined power level is 30%, and the actual input power level is close to 30%, then the duty cycle may be close to 50%. However, if the input power level is close to 10%, the duty cycle may be closer to 40% than 50%. In other words, an input power of 30% may correspond to a 50% duty cycle, while an input power of 1% may correspond to a 40% duty cycle. The relationship between the input power level and the duty cycle percent need not be linear, but may be adjusted to the components used in the circuit.

If the amplifier input power level then rises above the predetermined level, the duty cycle of the pulse width modulator increases towards 100%. The duty cycle may increase linearly until it reaches 100%. The duty cycle may increase linearly over time, or it may increase linearly corresponding to an input power level increase.

The heat level 202 of the heat sink is also monitored. If the heat level 202 of the heat sink rises above a predetermined level, the duty cycle of the pulse width modulator is decreased to a predetermined value, such as 50%. In FIG. 2, the predetermined heat level is represented by θ. According to one embodiment, θ is 75 degrees C. This level may correspond to a level beneath the maximum thermal tolerance of the amplifier, for example. If the temperature 202 of the heat sink drops below the predetermined value, the duty cycle returns to the state corresponding to the power output of the power supply. For example, if the amplifier input is below the predetermined amplifier input level, the duty cycle would return to the duty cycle value between 40% and 50%. If the amplifier input is above the predetermined level, the duty cycle would return to 100%.

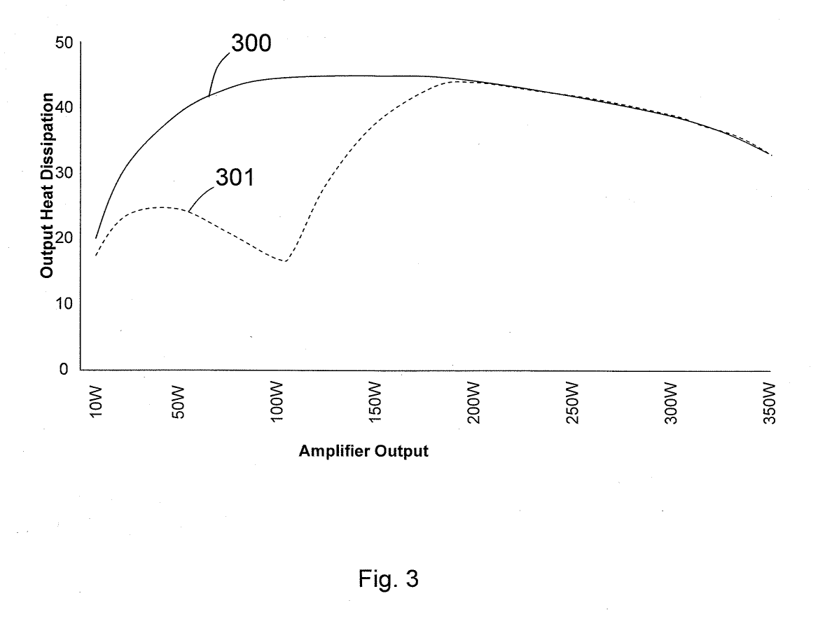

A system may employ either the first stage or the second stage, or it may employ both stages together. FIG. 3 illustrates the relationship between heat dissipated and the output power of the amplifier in a system employing only the first stage. The amplifier has a maximum power output of 350 W, and the first stage disengages around 100 W.

In a system without a first stage 300, the heat level at the heat sink increases rapidly when the amplifier output increases from 0 W to about 75 W. The heat level of the heat sink levels out when the amplifier output is between 75 W and 225 W, and the heat level drops off as the power increases above 225 W, since the amplifier operates more efficiently at levels close to 350 W than at levels close to 200 W. The system without the first stage 300 keeps the duty cycle from the PWM to the power supply at 100% regardless of output power levels. As seen in FIG. 3, the amplifier dissipates less heat when operating at a certain low power range than it does when operating at a high output power. Without the first stage 300, the amplifier reaches a maximum power dissipation around 100 W. It becomes more heat efficient, dissipating less heat per output watt, from about 100 W to 350 W.

In a system with the first stage implemented 301, the heat level of the heat sink stays low while the first stage is engaged. At about 100 W, the first stage disengages, and the output power is incrementally increased between 100 W and about 200 W, where the duty cycle of the pulse width modulator is 100%. While the first stage is engaged, the duty cycle from the PWM to the power supply is between 40% and 50%. With the first stage engaged 301, the amplifier is more heat efficient at lower output wattages, up to around 120 W. As with the system in which the first stage is not engaged 300, the power dissipation is high around 200 W and decreases between 200 W and 350 W. However, in the system with the first stage implemented 301, the amplifier is more power efficient at low output power, between about 0 W and 120 W, than at the highest power levels (350 W). Although this example describes an amplifier having a maximum power output of 350 W, an amplifier of any output power may be used, depending on the circuit requirements.

Overall heat output of the power supply and amplifier to the heat sink may not change between the system without the first stage and the system with the first stage. However, the first stage balances the heat level across the heat sink, which allows the amplifier to output more power before reaching its thermal limit.

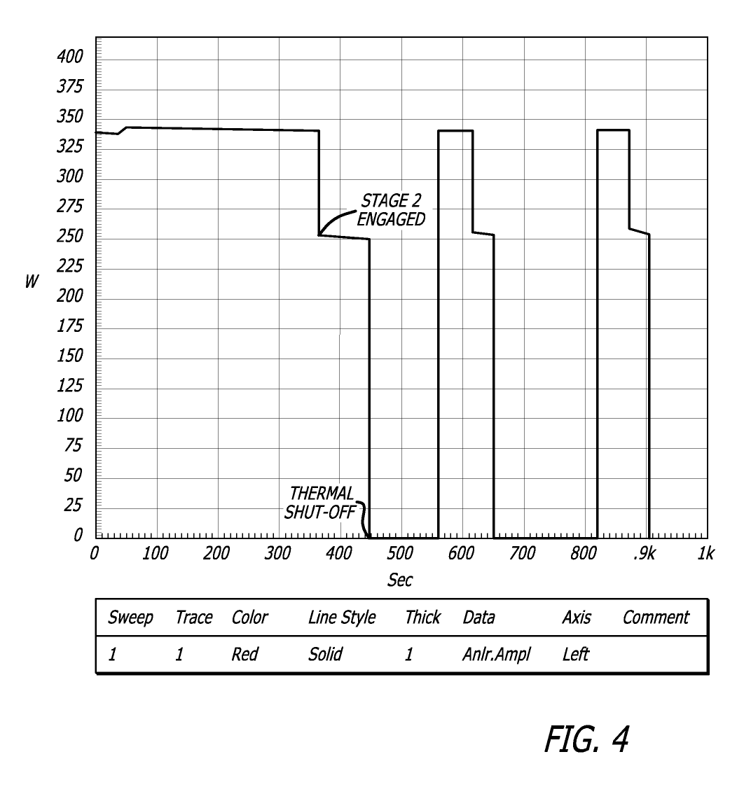

FIG. 4 illustrates the relationship between power output from the amplifier and time in a system with the second stage implemented. Between 0 seconds and about 375 seconds, power output is about 340 W. At about 375 seconds, the second stage engages, reducing power output of the amplifier from about 340 W to about 250 W. At about 450 seconds, the amplifier reaches its thermal limit and shuts off. At about 560 seconds, the amplifier cools enough to restart, and the process repeats.

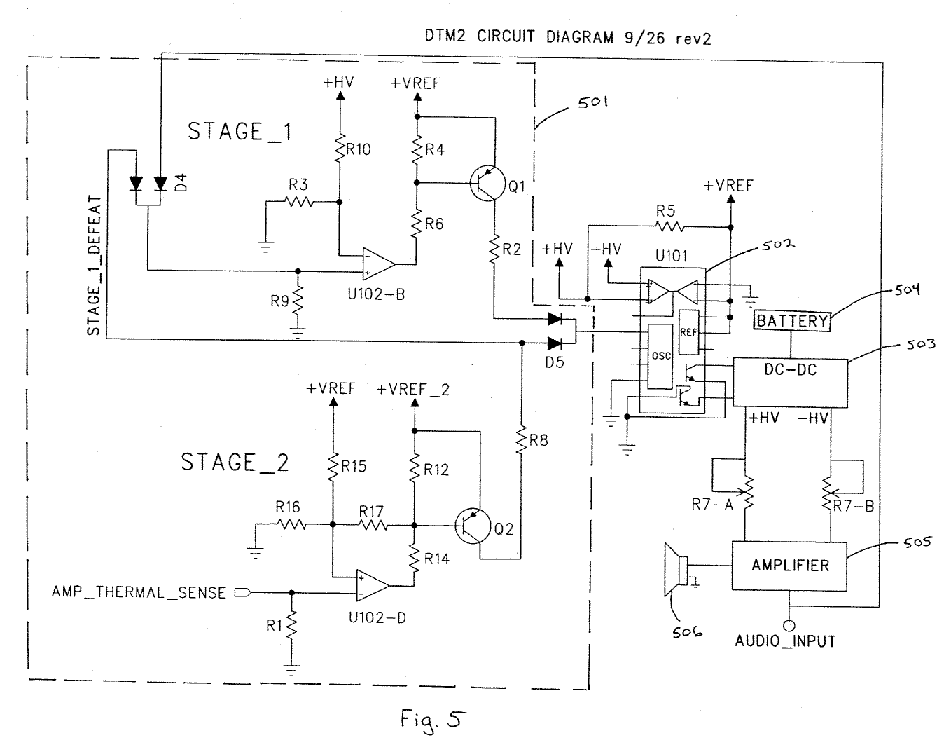

FIG. 5 illustrates a simplified schematic of a portion of a system implementing both stage 1 and stage 2. Monitoring circuit 501 receives inputs from the audio input, corresponding to stage 1, and a thermal sensor, corresponding to stage 2. If either stage 1 or stage 2 is engaged, it signals the pulse width modulator 502 to change a duty cycle to the power supply 503. The power supply 503 receives a voltage input from battery 504 and outputs a voltage to the amplifier 505. The amplifier receives the voltage from the power supply 503 and an audio input signal and outputs an amplified signal corresponding to the audio input signal to the speaker 506.

As discussed above, the monitoring circuit 501 detects whether the audio input signal to the amplifier 505 drops below a predetermined level. If the audio input signal drops below the predetermined level, the monitoring circuit 501 signals the pulse width modulator 502 to reduce the duty cycle of the pulse width modulator of the signal to the power supply 503. If the monitoring circuit 501 detects that the temperature of a heat sink reaches a predetermined level, as indicated by the thermal sensor signal, the monitoring circuit 501 signals the pulse width modulator 502 to reduce the duty cycle to the power supply 503.

A dynamic thermal management system according to any one of the above exemplary embodiments increases thermal symmetry of a power supply and amplifier circuit. Thus, the amount of time before the amplifier reaches its thermal limit is increased. The above exemplary embodiments achieve this efficiency with extremely low cost. The heat dissipation efficiency of the heat sink is increased. The system reduces or eliminates the need for inductors and other expensive power supply components.

The various embodiments described above are provided by way of illustration only and should not be construed to limit the claimed invention. Those skilled in the art will readily recognize various modifications and changes that may be made to the claimed invention without following the example embodiments and applications illustrated and described herein, and without departing from the true spirit and scope of the claimed invention, which is set forth in the following claims.

What is claimed is:

1. A thermal management system, comprising:
a power supply;
an amplifier connected to the power supply;
an output device connected to the amplifier; and
a monitoring circuit for managing a heat output of the power supply and the amplifier,
wherein the monitoring circuit determines an output heat level of each of the power supply and amplifier and balances a heat output of the amplifier with respect to the power supply.

2. The thermal management system according to claim 1, wherein the audio device is a speaker.

3. The thermal management system according to claim 1, wherein the amplifier is a fixed rail class amplifier.

4. The thermal management system according to claim 1, wherein the power supply comprises a battery.

5. The thermal management system according to claim 1, further comprising a pulse width modulation circuit connected between the monitoring circuit and the power supply,
wherein the monitoring circuit monitors an input signal to the amplifier, and
the monitoring circuit causes the pulse width modulation circuit to reduce a duty cycle of a modulated signal to the power supply when the input signal is below a predetermined level.

6. The method according to claim 5, wherein the predetermined level is an input level that corresponds to one third of full output power.

7. The thermal management system according to claim 5, wherein the monitoring circuit causes the pulse width modulation circuit to reduce the duty cycle of the modulated signal to a level between approximately 40% and 50% of a full duty cycle.

8. The thermal management system according to claim 1, further comprising a pulse width modulation circuit connected between the monitoring circuit and the power supply,
wherein the monitoring circuit causes the pulse width modulation circuit to reduce a duty cycle of a modulated signal to the power supply when a heat level of at least one of the power supply and the amplifier reaches a predetermined level.

9. The thermal management system according to claim 8, wherein the monitoring circuit causes the pulse width modulation circuit to reduce the duty cycle of the modulated signal to 50%.

10. The thermal management system according to claim 8, further comprising a heat sink for sinking heat from the power supply and the amplifier, wherein the monitoring circuit monitors the heat level of the heat sink to determine whether to reduce the duty cycle of the modulated signal to the power supply.

11. The thermal management system according to claim 10, further comprising a sensor, wherein the monitoring circuit monitors the heat level of the heat sink via the sensor.

12. A device for supplying signals to an audio device, comprising:
a power supply;
an amplifier connected to the power supply and such audio device; and
a monitoring circuit for managing a heat output of the power supply and the amplifier,
wherein the monitoring circuit determines an output heat level of each of the power supply and amplifier and balances a heat output of the amplifier with respect to the power supply.

13. The device according to claim 12, wherein the amplifier is a fixed rail class amplifier.

14. The thermal management system according to claim 12, wherein the power supply comprises a battery.

15. The device according to claim 12, further comprising a pulse width modulation circuit connected between the monitoring circuit and the power supply,
wherein the monitoring circuit monitors an input signal to the amplifier, and
the monitoring circuit causes the pulse width modulation circuit to reduce a duty cycle of a modulated signal from the pulse width modulation circuit to the power supply when the input signal is below a predetermined level.

16. The device according to claim 15, wherein the monitoring circuit causes the pulse width modulation circuit to reduce the duty cycle of the modulated signal to between approximately 40% and approximately 50%.

17. The device according to claim 12, further comprising a pulse width modulation circuit connected between the monitoring circuit and the power supply,
wherein the monitoring circuit causes the pulse width modulation circuit to reduce a duty cycle of a modulated signal to the power supply when a heat level of at least one of the power supply and the amplifier reaches a predetermined level.

18. The device according to claim 17, wherein the monitoring circuit causes the pulse width modulation circuit to reduce the duty cycle of the modulated signal to 50%.

19. The device according to claim 17, further comprising a heat sink for sinking heat from the power supply and the amplifier,
wherein the monitoring circuit monitors the heat level of the heat sink to determine whether to reduce the duty cycle of the modulated signal to the power supply.

20. The device according to claim 19, wherein the monitoring circuit causes the pulse width modulation circuit to reduce the duty cycle of the modulated signal to 50%.

21. The device according to claim 19, further comprising a sensor,
wherein the monitoring circuit monitors the heat level of the heat sink via the sensor.

22. A method for managing a heat output of a power management device for supplying signals to an output device, the method comprising:
monitoring an input signal to an amplifier,
determining whether an input signal level is below a predetermined level,
reducing a duty cycle of a modulated signal from a pulse width modulator to the power supply when the input signal level is below a predetermined level,
monitoring a heat level of at least one of the amplifier and power supply, and
balancing a heat output of the amplifier with respect to the power supply.

23. The method according to claim 22, wherein the predetermined level is an input level that corresponds to one third of full output power.

24. The method according to claim 22, wherein the duty cycle is reduced to a level between approximately 40% and approximately 50%.

25. A method according to claim 22, further comprising:
reducing the duty cycle of the modulated signal when the heat level of the amplifier or the power supply exceeds a predetermined level.

26. The method according to claim 25, wherein the power management device comprises a monitoring circuit and a heat sink,
wherein the heat sink sinks heat from the power supply and the amplifier, and
the monitoring circuit monitors the heat level of the power supply and the amplifier by monitoring a heat level of the heat sink.

27. The method according to claim 26, wherein the power management device comprises a pulse width modulation circuit connected between the monitoring circuit and the power supply,
wherein the monitoring circuit causes the pulse width modulation circuit to reduce the duty cycle of the modulated signal to the power supply.
